(19) United States
(12) Patent Application Publication
(10) Pub. No.: US 2007/0009816 A1
(43) Pub. Date: Jan. 11, 2007

(54) Method and system for photolithography

(76) Inventors: Rainer Pforr, Dresden (DE); Mario Hennig, Dresden (DE); Jens Reichelt, Dresden (DE); Thomas Muelders, Dresden (DE)

Correspondence Address: SLATER & MATSIL LLP, 17950 PRESTON ROAD, SUITE 1000, DALLAS, TX, 75252, US

(21) Appl. No.: 11/455,286

(22) Filed: Jun. 16, 2006

Related U.S. Application Data
(63) Continuation-in-part of application No. PCT/EP05/06560, filed on Jun. 17, 2005.

(51) Int. Cl. G03F 7/20

(52) U.S. Cl. 430/30; 430/22; 430/311

(57) ABSTRACT

A transparent optical element in a region between a photo mask and a light source of a photolithographic apparatus is provided having a plurality of attenuating elements being arranged in accordance with a first intensity correction function. The first intensity correction function is calculated from variations of characteristic feature size of structural elements of a resist pattern as compared to the nominal values of structural elements of a layout pattern. The variations of the characteristic feature size are divided into a first contribution being associated with the photolithographic apparatus and into a second contribution being associated with the photo mask.

This application is a continuation of co-pending International Application No. PCT/EP2005/006560, filed Jun. 17, 2005, which designated the United States and was not published in English, and is incorporated herein by reference.

### TECHNICAL FIELD

The invention relates to a method for photolithography. Further the invention relates to a system for photolithography. In particular the invention relates to a method for improving dimensional accuracy in a photolithographic system and to a photolithographic system.

### BACKGROUND

The manufacturing of integrated circuits aims for continuously decreasing feature sizes of the fabricated components and includes repeatedly projecting a pattern in a lithographic step onto a semiconductor wafer and processing the wafer to transfer the pattern into a layer deposited on the wafer surface or into the substrate of the wafer. This processing includes depositing a resist film layer on the surface of the semiconductor substrate, projecting a photo mask with the pattern onto the resist film layer and developing or etching the resist film layer to create a resist structure.

The resist structure is transferred into a layer deposited on the wafer surface or into the substrate in an etching step. Planarization and other intermediate processes may further be necessary to prepare a projection of a successive mask level. Furthermore, the resist structure can also be used as a mask during an implantation step. The resist mask defines regions in which the electrical characteristics of the substrate are altered by implanting ions.

The pattern being projected is provided on a photo mask. The photo mask is illuminated by a light source having a wavelength that is selected in a range from ultraviolet (UV) light to deep-UV in modern applications. The part of the light that is not blocked or attenuated by the photo mask is projected onto the resist film layer on the surface of a semiconductor wafer.

In order to manufacture patterns having line widths in the range of 70 nm or smaller, large efforts have to be undertaken to guarantee sufficient dimensional accuracy of patterns projected onto the resist film layer. The dimensional accuracy of patterns depends on many factors, e.g., the optical performance of the exposure tool and the characteristics of the resist film layer with respect to exposure dose in different regions on the wafer. As an example, aberration errors of the projection system of the exposure tool and the mask technology used for the photo mask influence dimensional accuracy of patterns projected onto the resist film layer.

Control of dimensional accuracy is performed by measuring the size of portions of distinct resist pattern of the current layer with an inspection tool. Here, a scanning electron microscope can be used to quantify the amount of deviation at certain positions on a wafer by measuring several patterns and comparing the results with the layout. Another possibility of assessing the accuracy of critical dimensions is related to the direct inspection of test patterns. Typically, so-called CD-SEM structures are used to quantify the amount of deviation from the design value, e.g., by using a SEM-tool.

A method for correcting dimensional inaccuracies is described in WO 2005/008333 A2. In this document, a method for compensating for critical dimension (CD) variations of pattern lines of a wafer is disclosed, wherein the CD of the corresponding photo mask is corrected. As shown in FIG. 11, the photo mask 110 comprises a transparent substrate having two substantially opposite surfaces, i.e., a back surface and a front surface. On the front surface an absorbing pattern 112 is provided. After determining CD variations across regions of a wafer exposure field relating to the photo mask, shading elements SE are provided within the substrate of the photo mask 110 in regions that correlate to regions of the wafer exposure field where CD variations greater than a predetermined target value were determined. The shading elements attenuate light passing through the regions, so as to compensate for the CD variations on the wafer and hence provide an improved CD tolerance wafer. The provision of shading elements is carried out by irradiating pulsed laser radiation through the back surface into the photo mask and substantially opposite pattern lines.

With decreasing feature sizes of patterns the precise determination of dimensional accuracy of patterns gets even more important. Failing to control dimensional accuracy of patterns would ultimately result in a low yield of the produced circuits.

### SUMMARY OF THE INVENTION

It is accordingly an object of the invention to improve the accuracy dimensional accuracy in a photolithographic system.

It is a particular object to improve the dimensional accuracy in a photolithographic system used in semiconductor manufacturing. It is a further object of the invention to increase the yield and reduce the costs in semiconductor manufacturing.

These and other objects together with technical advantages are generally achieved by the present invention that, according to a first aspect provides for a method for improving dimensional accuracy in a photolithographic system. The system includes a layout pattern having a plurality of structural elements each having a characteristic feature size being described by a nominal value. A photo mask having a mask pattern corresponding to the layout pattern is provided, as well as a photolithographic apparatus having a light source and being capable to accommodate the photo mask. The mask pattern is projected on a photo resist layer on a surface of a substrate using the photolithographic apparatus. A resist pattern having a plurality of structural elements corresponding to the layout pattern is formed, wherein each of the structural elements have at least one characteristic feature size. Variations of the at least one characteristic feature size of the structural elements of the resist pattern as compared to the nominal values of the structural elements of the layout pattern are determined. The variations of the at least one characteristic feature size are apportioned into a first contribution being associated with the photolithographic apparatus and into a second contribution being associated with the photo mask. A first intensity correction function is calculated according to the first contribution of the variation of the characteristic feature size. A transparent optical element having a plurality of attenuating elements being arranged in accordance with the first intensity correction function is provided, and the transparent optical element in the photolithographic apparatus is introduced in a region between the photo mask and the light source, so as to improve the dimensional accuracy during projection of the mask pattern.

According to a second aspect, a method for improving dimensional accuracy in a photolithographic system is provided. The system includes a layout pattern having a plurality of structural elements each having a characteristic feature size being described by a nominal value. A photo mask having a mask pattern corresponding to the layout pattern is provided, as well as a photolithographic apparatus having a light source and being capable to accommodate the photo mask. The mask pattern on a photo resist layer is projected on a surface of a substrate using the photolithographic apparatus. A resist pattern having a plurality of structural elements corresponding to the layout pattern is formed, wherein each of the structural elements have at least one characteristic feature size. Variations of the at least one characteristic feature size of the structural elements of the resist pattern as compared to the nominal values of the structural elements of the layout pattern are determined. The variations of the at least one characteristic feature size are apportioned into a first contribution being associated with the photolithographic apparatus and into a second contribution being associated with the photo mask. A first intensity correction function is calculated according to the first contribution of the variation of the at least one characteristic feature size. A second intensity correction function is calculated according to the second contribution of the variation of the characteristic feature size. A transparent optical element having a plurality of attenuating elements being arranged in accordance with the first intensity correction function and having a further plurality of attenuating elements being arranged in accordance with the second intensity correction function is provided, and the transparent optical element in the photolithographic apparatus is introduced in a region between the photo mask and the light source, so as to improve the dimensional accuracy during projection of the mask pattern.

In a further embodiment, the attenuating elements being arranged in accordance with the first intensity correction and the attenuating elements being arranged in accordance with the second intensity correction are arranged on the front surface of the transparent optical element.

In a further embodiment, the attenuating elements being arranged in accordance with the first intensity correction are arranged on the front surface of the transparent optical element and the attenuating elements being arranged in accordance with the second intensity correction are arranged on the back surface of the transparent optical element.

In a further embodiment, the attenuating elements being arranged in accordance with the first intensity correction are arranged on the front surface of the transparent optical element and the attenuating elements being arranged in accordance with the second intensity correction are arranged by creating shading elements within the photo mask of the transparent optical element.

In a further embodiment, an iterative approach can be used to further reduce the variations of the at least one further characteristic feature size of the structural elements of the resist pattern as compared to the nominal values of the structural elements of the layout pattern. In order to accomplish this, a further transparent optical element is generated, which includes the photo mask having a mask pattern corresponding to the layout pattern, and the transparent optical element having a plurality of attenuating elements being arranged in accordance with the first intensity correction function. The photolithographic apparatus having a light source and being capable to accommodate the photo mask is provided. The mask pattern on a photo resist layer is projected on a surface of a further substrate using the photolithographic apparatus. A further resist pattern having a plurality of structural elements corresponding to the layout pattern is formed, wherein each of the structural elements have at least one further characteristic feature size. Remaining variations of the at least one further characteristic feature size of the structural elements of the resist pattern as compared to the nominal values of the structural elements of the layout pattern are determined. A further intensity correction function according to the further contribution of the variation of the characteristic feature size is calculated. A further transparent optical element having a plurality of attenuating elements being arranged in accordance with the further intensity correction function is provided, and the further transparent optical element in the photolithographic apparatus is introduced in a region between the photo mask and the light source, so as to improve the dimensional accuracy during projection of the mask pattern.

The steps of iteratively determining intensity correction functions and according attenuating elements in the transparent optical element may be continued to further reduce the remaining variations of the at least one characteristic feature size of the structural elements of the resist pattern as compared to the nominal values of the structural elements of the layout pattern.

In order to keep the overall optical transmission of the transparent optical elements at a high level, one may combine two or more of the transparent optical elements into a single transparent optical element by determining a plurality of attenuating elements having the same effect on the variations of the at least one characteristic feature size of the structural elements of the resist pattern as compared to the nominal values of the structural elements of the layout pattern. The combination can for example be done by introducing the arrangement of attenuating elements of the individual trans-parent optical elements on the same or on different surfaces of the combined transparent optical element. Also a new arrangement of attenuating elements may be determined for the combined transparent optical element.

Yet another solution to the object is provided by a system for improving dimensional accuracy in a photolithographic system. The system includes a layout pattern having a plurality of structural elements each having a characteristic feature size being described by a nominal value. A photo mask having a mask pattern corresponding to the layout pattern, and a photolithographic apparatus having a light source and being capable to accommodate the photo mask and to project the mask pattern on a photo resist layer on a surface of a substrate are also included. A means for forming a resist pattern having a plurality of structural elements corresponding to the layout pattern is provided, wherein each of the structural elements have at least one characteristic feature size. A means for determining variations of the at least one characteristic feature size of the structural elements of the resist pattern as compared to the nominal values of the structural elements of the layout pattern, and a means for apportioning the variations of the characteristic feature size into a first contribution being associated with the photolithographic apparatus and into a second contribution being associated with the photo mask are provided. The system further includes a means for calculating a first intensity correction function according to the first contribution of the variation of the characteristic feature size, a transparent optical element having a plurality of attenuating elements being arranged in accordance with the first intensity correction function, and means for introducing the transparent optical element in the photolithographic apparatus in a region between the photo mask and the light source, so as to improve the dimensional accuracy during projection of the mask pattern.

### BRIEF DESCRIPTION OF THE DRAWINGS

The above features of the present invention will be more clearly understood from consideration of the following descriptions in connection with accompanying drawings in which:

FIG. 1 illustrates an arrangement comprising an exposure tool with a wafer and a photo mask in a side view;

FIGS. 2A to 2D show a layout pattern, a mask pattern and a resist pattern projected on the surface of a semiconductor wafer using the projection apparatus according to FIG. 1 and a intensity distribution during projection of the mask pattern on the surface of a semiconductor wafer;

FIG. 3 diagrammatically shows a photo mask and a transparent optical element in a side view according to an embodiment of the invention;

FIG. 4 diagrammatically shows a transparent optical element in a side view according to a further embodiment of the invention;

FIG. 5 diagrammatically shows a transparent optical element in a side view according to a further embodiment of the invention;

FIG. 6 diagrammatically shows a transparent optical element in a top view according to a further embodiment of the invention;

FIG. 7 diagrammatically shows a photo mask and a transparent optical element in a side view according to a further embodiment of the invention;

FIG. 8 illustrates a further arrangement comprising an exposure tool with a wafer and a photo mask in a side view;

FIG. 9 illustrates a further arrangement comprising an exposure tool with a wafer to mask in a side view according to a further embodiment of the invention;

FIG. 10 diagrammatically shows a transparent optical element in a top view to a further embodiment of the invention; and

FIG. 11 diagrammatically shows a photo mask in a side view according to the prior

The following list of reference symbols can be used in conjunction with the Figures:

| | | | |
|---|---|---|---|
| 5 | projection apparatus | 41, 44 | structural elements |
| 10, 110 | photo mask | 46 | characteristic feature size (mask) |
| 12, 112 | mask pattern | 48 | characteristic feature size (mask) |
| 14 | light source | 50 | characteristic feature size (resist) |
| 16 | projection lens | 52 | intensity distribution |
| 20, 20′ | resist layer | 60, 60′ | attenuating elements |
| 22 | substrate | 62 | first alignment mark |
| 24 | surface of substrate | 64 | second alignment mark |
| 26 | illumination optics | 66 | antireflective coating |
| 28 | lens | 68 | antireflective coating |
| 30 | optical element | 80 | rotating plate |
| 32 | front side | 82 | conjugated plane |
| 34 | back side | 84 | further regions |
| 40 | layout pattern | 90 | frame member |
| 42 | nominal size | | |

### DETAILED DESCRIPTION OF ILLUSTRATIVE EMBODIMENTS

A presently preferred embodiment of the method and the system according to the invention is discussed in detail below. It is appreciated, however, that the present invention provides many applicable inventive concepts that can be embodied in a wide variety of specific contexts. The specific embodiments discussed are merely illustrative of specific ways to apply the method and the system of the invention, and do not limit the scope of the invention.

In the following, embodiments of the method and the system are described with respect to improving dimensional accuracy during lithographic projection of a layer of an integrated circuit. The invention, however, might also be useful for other products, e.g., liquid crystal panels or the like.

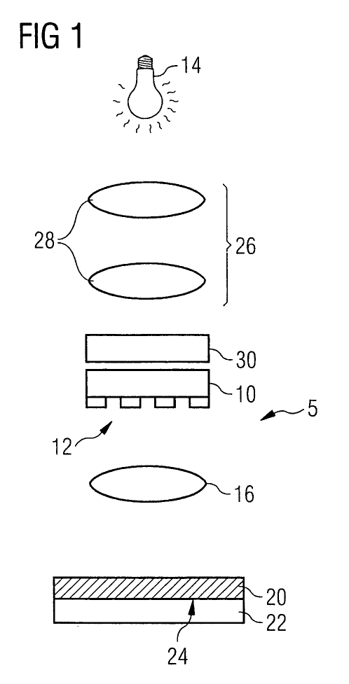

With respect to FIG. 1 a set-up of a lithographic projection apparatus 5 in a side view is shown. It should be appreciated that FIG. 1 merely serves as an illustration, i.e., the individual components shown in FIG. 1 neither describe the full functionality of a lithographic projection apparatus 5 nor are the elements shown true scale.

The projection apparatus 5 comprises a light source 14, which is, e.g., an Excimer laser with 193 nm wavelength. An illumination optics 26 projects the light coming from the light source 14 through a photo mask 10 into an entrance pupil of the projection system. The illumination optics 26 can be comprised of several lenses 28, as shown in FIG. 1, which are arranged between the light source 14 and photo mask 10.

The photo mask 10 comprises a mask pattern 12, i.e., being composed of light absorptive or light attenuating elements. Light absorptive elements can be provided by e.g., chrome elements. Light attenuating elements can be provided by, e.g., Molybdenum-silicate elements.

The light passing the photo mask 10, i.e., not being blocked or attenuated by the above-mentioned elements, is projected by projection lens 14 onto the surface 24 of a semiconductor wafer 22. The pattern projected on the semiconductor wafer 22 is usually scaled down, e.g., by factor of 4.

The semiconductor wafer 22 has a substrate onto which a photo resist film layer 20 is deposited onto which the mask pattern 12 is projected. After developing the photo resist film layer 20 a three-dimensional resist pattern 20′ is formed on the surface of the substrate 22 by removing those parts of the photo resist film layer 20 that are exposed with an exposure dose above the exposure dose threshold of the resist film layer 20.

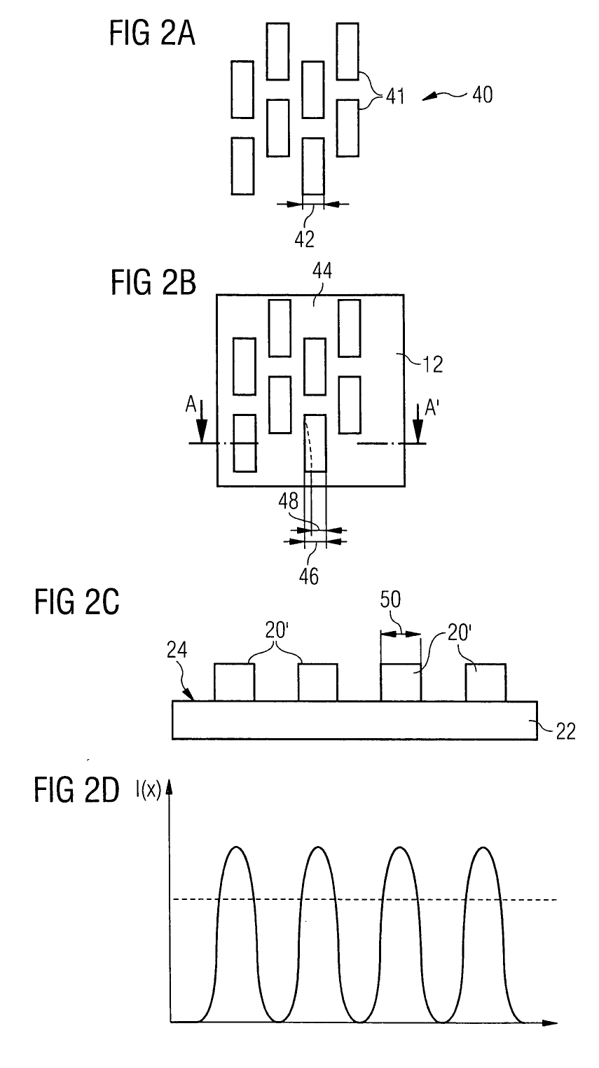

Referring now to FIG. 2A, a layout pattern 40 is shown, which has a plurality of structural elements 41. The layout pattern 40 is, e.g., provided by a computer program. Each of the structural elements 41 is a line-shaped pattern that has a characteristic feature size. The characteristic feature size can be described by the width of the line-shaped patterns, which are further referred to as its nominal value 42.

Referring now to FIG. 2B, a mask pattern 12 is shown, which corresponds to the layout pattern 40. The mask pattern 12 has a plurality of structural elements 44, e.g., openings being arranged in a chrome layer. The corresponding size of the openings can be described by the width 46 of the structural elements 44. It should be noted, however, that other features might be included in the mask pattern 12 in order to improve resolution and/or pattern fidelity in the lithographic projection step. As an example, sub-resolution sized assist features or scattering bars can be implemented in the mask pattern. Furthermore, the one-to-one correspondence between the layout pattern 40 and mask pattern 12 serves only as an illustration. In modern mask technology, e.g., using attenuated or chrome-less phase shifting masks, correspondence between the layout pattern 40 and mask pattern 12 might not be immediately apparent.

Referring now to FIG. 2C, the resist pattern 20′ after projecting the mask pattern 12 onto the surface of the substrate 22 is shown using the projection apparatus 5 according to FIG. 1. The resist pattern 20′ is shown in a side view across the line from A to A′, which is indicated in FIG. 2B. Each of the structural elements of the resist pattern 20′ is again described by a characteristic features size 50.

The corresponding intensity distribution on the surface of substrate 22 during lithographic projection is shown in FIG. 2D. In addition, the exposure threshold is shown as a dashed line. The local exposure or intensity dose is one parameter that affects the quality of the projection and hence the dimensional accuracy of the projection step.

In order to improve the dimensional accuracy of the projection step, characteristic features sizes 50 of the structural elements of the resist pattern 20′ are compared to the nominal values 42 of the structural elements 41 of the layout pattern 40. This allows determining variations of the characteristic features sizes 50 of the structural elements of the resist pattern 12 with respect to the nominal values of the structural elements of the layout pattern 40.

These variations can have different sources. One possibility is related to uncertainties during mask fabrication, which may lead to slightly different dimensions of the mask patterns. This results, e.g., in a varying width 48 of the openings shown in FIG. 2B. Another possible source is given by local variations of the intensity emitted from light source 14 or imperfections of the projection optics 16.

In principle, both sources can be disentangled by performing various measurements with known mask patterns and/or intensity distributions from light emitted from light source 14. Accordingly, it is possible to divide the variations of the characteristic features sizes 50 into a first contribution being associated with the photolithographic apparatus 5 and into a second contribution being associated with the mask pattern 12 of photo mask 10. Based on the first contribution of the variation of the characteristic features sizes a first intensity correction function can be calculated, which leads to an improved features size on the resist pattern when applied to the photolithographic system.

It should be noted, that the characteristic features sizes 50 of the resist pattern can also be represented by several geometric quantities. For example, specific patterns like deep trench patterns used in DRAM manufacturing are sensitive both for width and length of the corresponding layout pattern.

In addition, a second intensity correction function can be calculated on the basis of the second contribution, which describes the influence of the variation of the mask pattern due to tolerances in the mask fabrication process, as described in FIG. 2B.

In other words, the intensity of the light emitted from light source 14 is locally modified, so as to improve the dimensional accuracy of the layout pattern 40 during projection of mask pattern 12.

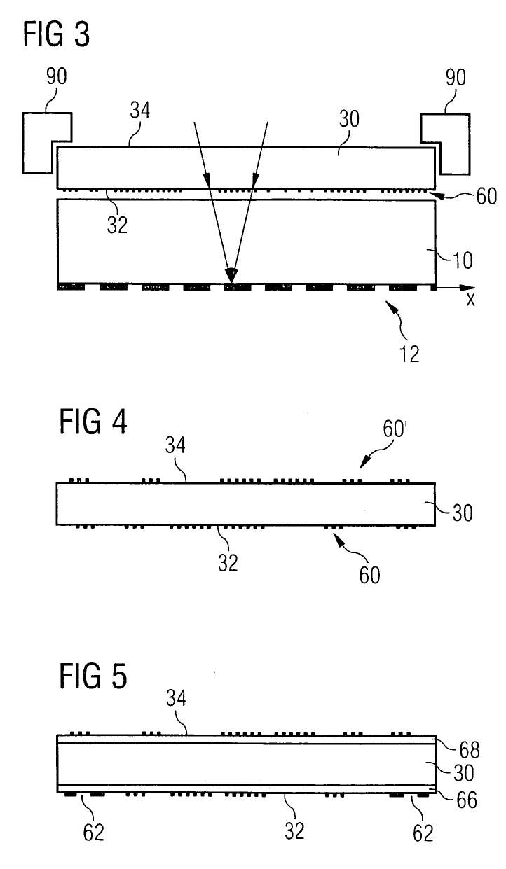

Both, the first intensity correction function and the second intensity correction function are now used to provide attenuating elements. The attenuating elements 60 are arranged on a transparent optical element 30, as shown in FIG. 3. The attenuating elements are arranged in accordance with the first intensity correction function and the second intensity correction function. The attenuating elements provide the required local intensity correction of the light emitted from light source 14, so as to improve the dimensional accuracy of the layout pattern 40 during projection of the mask pattern 12.

The transparent optical element 30 is inserted into the photolithographic apparatus 5 in a region between the photo mask 10 and the light source 14, so as to improve the dimensional accuracy during projection of the mask pattern 12. As shown in FIG. 3, transparent optical element 30 is located above the photo mask 10. Other suitable locations are described below.

The necessary change of intensity of the light emitted from light source 14 is described by the first intensity correction function and the second intensity correction function. Mathematically, the local transmittance change ΔT of the transparent optical element to correct for a CD deviation denoted ΔCD with respect to the nominal value CDnom is determined by the formula
ΔT=ΔCD/(dCD/d(D/Dnom)),
whereas (dCD/d(D/Dnom)) is the gradient of the CD-versus-dose curve (CD=CD(D/Dnom) at the nominal dose Dnom. In case of positive tone resist and resist lines to be corrected all lines smaller than the maximum value within the image field are corrected such that the reach the value of the line of maximum CD. To reach the target CD after the correction an adjusted dose (in the specific case a small enlargement) will be used.

As shown in FIG. 3, the transparent optical element 30 is provided as a plate. In order to achieve the desired transparency, a quartz plate can be used for the transparent optical element 30. The transparent optical element 30 has a front surface 32 and a back surface 34. The front surface and the back surface are arranged substantially parallel to each other. The front surface 32 facing in the direction to the back side of the photo mask 10.

In order to facilitate mounting of the transparent optical element 30, a frame member 90 covering the outer edges of the transparent optical element 30 is provided, e.g., fabricated as a metal frame. The transparent optical element 30 is attached to the frame member 90, e.g., by gluing. It is also envisaged to mount the transparent optical element 30 to the photo mask 10 such that it serves as a backside pellicle for the photo mask 10. Accordingly, the transparent optical element 30 is mounted together with the frame member 90 to the photo mask 10, so as to achieve a gas tight sealing of the backside of the photo mask 10, e.g., by gluing the frame member 90 to the backside of the photo mask 10.

In a first example, the attenuating elements 60 are optically opaque with respect to the light transmitted from the light source 14 in order to achieve the desired intensity correction. The attenuating elements 60 are formed in varying dimensions and densities so as to resemble the first intensity correction function. The attenuating elements 60 are fabricated using chrome, as an example.

Alternatively, the attenuating elements 60 can be provided as semi-transparent elements with respect to the light transmitted from the light source 14. Again, the attenuating elements 60 resemble the first intensity correction function. Semi-transparent elements can be achieved by using e.g., molybdenum silicide for attenuating elements 60.

In a further alternative, the attenuating elements 60 can be provided a phase grating elements on the back surface or the front surface of the transparent optical element. In this embodiment, the phase grating elements are arranged on a grid on the respective surface of the transparent optical element 30. The phase grating elements are formed by etching recesses into the transparent optical element at a certain depth and in a certain pitch. The pitch of the phase grating elements is chosen such that all higher orders of the resulting diffracted light no longer reach the substrate by imaging of the photo mask but are absorbed in the columns of the projection lens 16. By selecting the depth of the phase grating elements, the intensity of the zeroth order of the light passing through the optical element is changed and the attenuating elements 60 are formed. Again, the attenuating elements 60 are arranged such that the first intensity correction function is resembled.

In a further alternative, the attenuating elements 60 can be created as shading elements within the quartz plate of the transparent optical element, as described above by employing a pulsed laser.

As shown in FIG. 3, the attenuating elements 60 are arranged on the front surface 32 of the transparent optical element 30. Accordingly, the attenuating elements 60 are formed as opaque elements, shading elements or semi-transparent elements in accordance with the first intensity correction and with the second intensity correction.

Referring now to FIG. 4, an alternative embodiment is shown. FIG. 4 shows the transparent optical element 30 in a side view. Those attenuating elements 60, which are arranged in accordance with the first intensity correction, are arranged on the front surface 32 of the transparent optical element 30. The attenuating elements 60 are arranged in accordance with the second intensity correction on the back surface 34 of the transparent optical element 30.

In FIG. 5, a further embodiment is shown. The front surface of the transparent optical element 30 is covered by an antireflective coating 66, e.g., as thin film of a suitable material. Furthermore, the back surface of the transparent optical element 30 is covered by an antireflective coating 68 as well. Providing antireflective coating 66, 68 ensures that during a lithographic projection step no unwanted light reflections are emitted from the transparent optical element 30. Without these measures, unwanted light reflections could possibly reach the resist film layer 20 and degrade the pattern to be printed on the substrate 22.

The transparent optical element 30 provides a local intensity correction using attenuating elements 60. Accordingly, precise mounting of the transparent optical element 30 with respect to the photo mask 10 is important. In order to facilitate mounting of the transparent optical element 30, alignment marks can be employed.

As shown in FIG. 5, the transparent optical element 30 further includes structural elements forming a first alignment mark 62. The first alignment mark 62 is formed on the front surface 32 of the transparent optical element 30.

Furthermore, the photo mask is also provided with at least one second alignment mark (not shown in FIG. 5). In order to achieve an alignment in several directions, two or more alignment marks can be foreseen.

In a first embodiment, the second alignment mark is arranged on the front surface, i.e., the surface that includes the mask pattern 12. As an example, the second alignment mark can be formed during a mask lithography step for producing the mask pattern 12. It is, however, also envisaged, to arrange the second alignment mark on the back surface of the photo mask 10. The back surface is facing in the direction to the transparent optical element 30.

The first alignment 62 mark and the respective second alignment mark are formed, e.g., as a box-in-box or box-in-frame or frame-in-frame structure similar to overlay marks employed in photolithography. In addition, further alignment marks may be formed in each corner region of the transparent optical element 30.

During mounting or introducing of the transparent optical element 30 into the photolithographic apparatus 5, the first alignment mark 62 and the second alignment mark are inspected. For the inspection step, an optical microscope can be used. Thus, an alignment of the transparent optical element 30 and the photo mask 10 with respect to each other is performed in two directions.

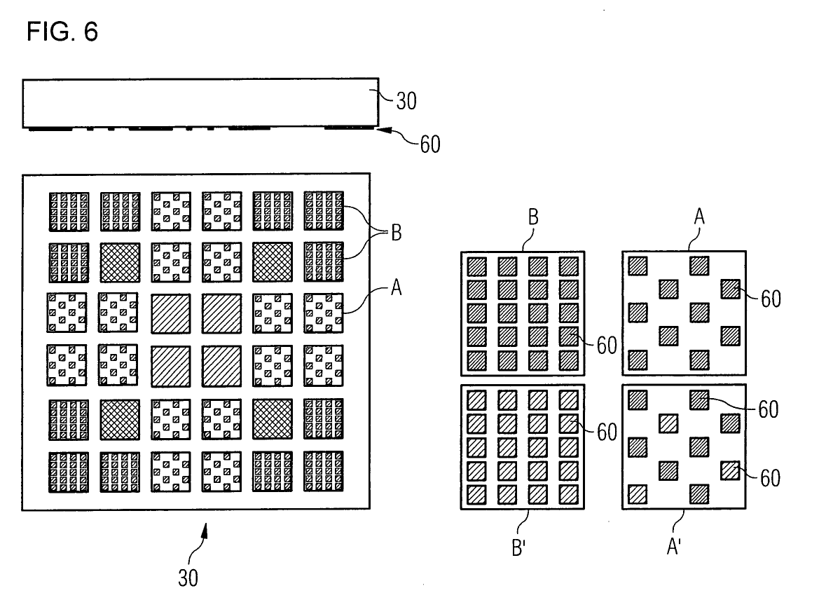

Referring now to FIG. 6, an exemplary embodiment of the transparent optical element 30 is shown in a top view. The attenuating elements 60 are formed as rectangular shapes having varying densities over the surface of the transparent optical element 30. The varying densities are indicated schematically by different shaded areas A and B. As it is shown in the insert in the lower right corner, the attenuating elements 60 are formed as opaque elements with different densities, thus providing different levels of attenuating light from the light source 14. In addition, it is shown that attenuating elements 60 in the area B′ are formed as semi-transparent elements or as a mixture between opaque and semi-transparent elements in area A′.

The minimum size of the attenuating elements 60 are chosen such that patterning of the transparent optical element 30 is achievable by, e.g., an optical mask writing tool. Advantageously, patterning of the transparent optical element 30 can be performed using cheap and simple process techniques, thus avoiding electron beam writing or other more complex mask processing steps.

In addition, it is also possible to prepare a set of attenuating elements 60 as a mask that can then be used in a mask writing stepper tool. Furthermore, opaque and semi-transparent attenuating elements 60 can be placed on the same transparent optical element 30.

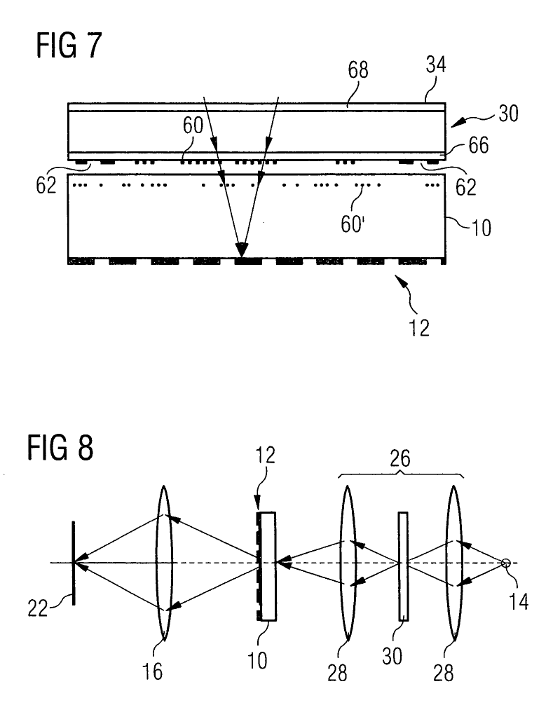

Referring now to FIG. 7, an alternative embodiment is shown. FIG. 7 shows photo mask 10 and transparent optical element 30 in a side view. The attenuating elements being arranged in accordance with the first intensity correction are arranged on the front surface 32 of the transparent optical element 30. The attenuating elements 60′ are arranged in accordance with the second intensity correction and are created as shading elements within the photo mask 10, as described above by employing a pulsed laser.

The embodiments as described with respect to FIG. 7 offers the possibility to correct for dimensional inaccuracies caused by different sources. The transparent optical element 30 addresses the intensity correction associated with, e.g., the photolithographic apparatus 5, while the shading elements within the photo mask 10 are chosen according to the second intensity correction associated with the photo mask 10.

Advantageously, the optical element 30 is prepared for each photolithographic apparatus 5 individually. The photo mask 10 with the shading elements is prepared as an individual feature of photo mask 10. By combining the optical element 30 with the photo mask 10 in a respective projection apparatus 5, an improved dimensional accuracy during lithographic projection is achieved. When inserting the photo mask 10 into different photolithographic apparatus 5, the respective optical element 30 provides the corrections associated with the individual photolithographic apparatus 5.

As an alternative to the embodiment described with respect to FIG. 7, the attenuating elements 60′ can also be formed as phase grating elements on the back side of photo mask 10, as described above. Again, the attenuating elements 60′ are arranged such that the second intensity correction function is resembled. The required intensity correction is provided by choosing the depth of the phase grating elements.

According to the embodiments shown in FIGS. 1 to 7, it should be noted that the attenuating elements 60 or 60′ can also be derived from a plurality of first and second intensity correction functions being averaged over different mask types, projection apparatus or illumination conditions. Thus, the transparent optical element 30 can be used for different exposure set-ups or illumination conditions.

Referring now to FIG. 8, an alternative placement of the optical element 30 is described. FIG. 8 shows a photolithographic apparatus 5 in a side view. The projection apparatus further comprises an illumination optics 26 having at least two lenses 28. According to the embodiments described with respect to FIGS. 1 to 8, the optical element 30 is placed above the photo mask 10, i.e., a few millimeters behind the plane defined by the front face containing the mask pattern 12 of photo mask 10. Depending on the thickness of the photo mask 10, a typical value is in the order of 4 mm to 8 mm.

Alternatively, the optical element 30 is positioned between the two lenses 28. In order to achieve a sharp image of the mask pattern 12 of photo mask 10, the plane defined by the front face of photo mask 10 translates into a conjugated plane 82 within the illumination optics 26. The transparent optical element 30 can be placed within the illumination optics 26 between the two lenses 28 as well.

In order to achieve the same imaging properties as if the optical element 30 would be placed a few millimeters distance above the photo mask 10, the optical element 30 needs to be placed in a defocused position with respect to the mask pattern plane. In this embodiment, the optical element 30 is placed a certain distance from a conjugated plane of the mask pattern of the photo mask 10 within the illumination optics 26. The certain distance from the conjugated plane of the mask pattern of the photo mask 10 is in the range of between about 1 mm and about 10 mm.

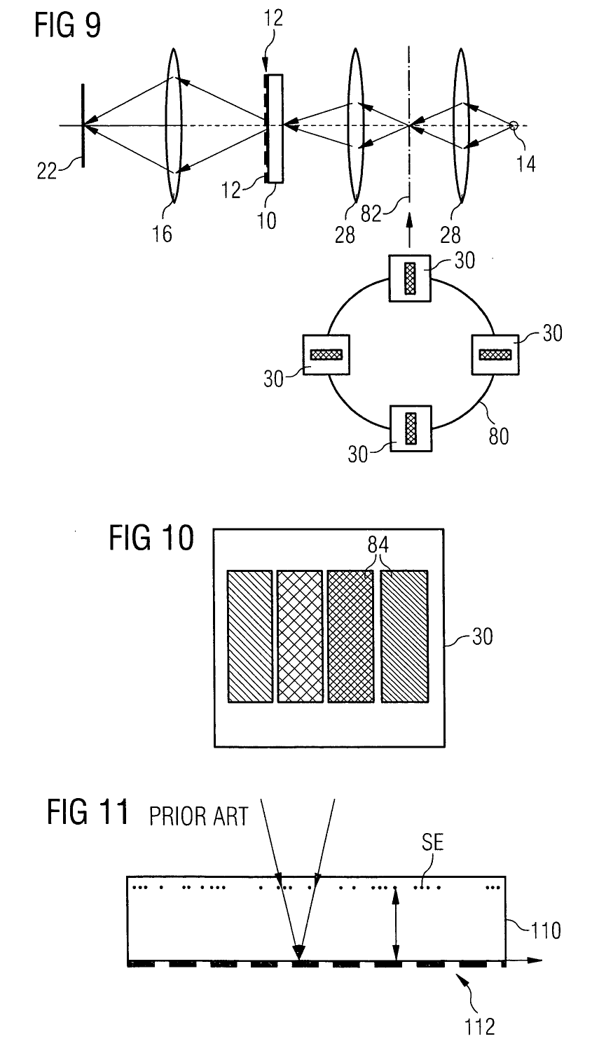

As an example, a wafer scanner can be used as photolithographic apparatus 5. A wafer scanner has an illumination slit (not shown in FIG. 9). Similar as above, the optical element 30 is positioned a certain distance from an intermediate plane of the illumination slit within the illumination optic. Again, the certain distance from the intermediate plane of the illumination slit is selected between about 1 mm and about 10 mm.

In a further embodiment shown in FIG. 10, the transparent optical element 30 has one or more further regions 84. Each of the further regions 84 are provided with an individual further plurality of attenuating elements. Thus, for different operating conditions, e.g., different illumination conditions or different masks, different regions 84 can be selected.

The respective region 84 on the transparent optical element 30 is selected, e.g., according to different mask patterns and/or different projection conditions used for lithographic processing. This allows to swiftly adapt the transparent optical element with respect to different intensity correction requirements.

In a further embodiment, the respective region 84 on the transparent optical element 30 is selected according to the image field on the substrate 20, which is exposed by the projection apparatus. Frequently further substrate processing such as polishing or etching results in characteristic feature sizes exhibiting a radial dependence or critical dimension distribution. According to the further embodiment, different regions 84 on the transparent optical element 30 are chosen resulting in different characteristic feature sizes of the resist pattern. Thus, the radial dependence on the substrate can be largely eliminated improving dimensional accuracy even further.

In general, the respective regions 84 on the transparent optical element 30 can be arranged in accordance with the one or more third intensity correction functions that are provided alternatively or in addition to the above-described first and second intensity correction functions.

A further embodiment is shown in FIG. 9. There, the transparent optical element 30 has again one or more further regions 84, which are provided on separate transparent plates.

The separate transparent plates 30 are mounted on a rotary plate 80, which is inserted into the projection apparatus 5. The separate transparent plates 30 are preferably positioned in the above-described distance from the conjugated plane 82.

The respective separate transparent plate is selected according to the mask pattern and/or exposure field of the projection apparatus.

According to this embodiment, adapting the transparent optical element with respect to different intensity correction requirements is achieved.

What is claimed is:

1. A method for improving dimensional accuracy in a photolithographic system, the method comprising:
providing a layout pattern having a plurality of structural elements each having a characteristic feature size being described by a nominal value;
providing a photo mask having a mask pattern corresponding to the layout pattern;
providing a photolithographic apparatus having a light source and being capable to accommodate the photo mask;
projecting the mask pattern on a photo resist layer on a surface of a substrate using the photolithographic apparatus;
forming a resist pattern having a plurality of structural elements corresponding to the layout pattern, wherein each of the structural elements have at least one characteristic feature size;
determining variations of the at least one characteristic feature size of the structural elements of the resist pattern as compared to the nominal values of the structural elements of the layout pattern;
apportioning the variations of the at least one characteristic feature size into a first contribution being associated with the photolithographic apparatus and into a second contribution being associated with the photo mask;
calculating a first intensity correction function according to the first contribution of the variation of the at least one characteristic feature size;
providing a transparent optical element having a plurality of attenuating elements being arranged in accordance with the first intensity correction function; and
introducing the transparent optical element in the photolithographic apparatus in a region between the photo mask and the light source, so as to improve the dimensional accuracy during projection of the mask pattern.

2. The method according to claim 1, wherein the step of providing a transparent optical element comprises providing the transparent optical element as a plate having a front surface and a back surface, wherein the front surface and the back surface are arranged substantially parallel to each other and wherein the front surface is facing the photo mask.

3. The method according to claim 2, wherein the front surface of the transparent optical element is covered by an antireflective coating.

4. The method according to claim 2, wherein the back surface of the transparent optical element is covered by an antireflective coating.

5. The method according to claim 2, wherein the transparent optical element further includes structural elements forming a first alignment mark.

6. The method according to claim 5, wherein the first alignment mark is formed on the front surface of the transparent optical element.

7. The method according to claim 5, wherein providing a photo mask comprises providing a second alignment mark on a surface of the photo mask.

8. The method according to claim 7, wherein introducing the transparent optical element in the photolithographic apparatus in a region between the photo mask and the light source comprises:
inspecting the first alignment mark and the second alignment mark; and
aligning the transparent optical element and the photo mask with respect to each other.

9. The method according to claim 8, wherein the step of inspecting the first alignment mark and the second alignment mark is performed by using an optical microscope.

10. The method according to claim 7, wherein the first alignment mark and the second alignment mark are formed as a box-in-box or box-in-frame or frame-in-frame structure.

11. The method according to claim 7, wherein further first alignment marks and respective further second alignment marks are provided, so as to perform an alignment in at least two directions between the transparent optical element and the photo mask.

12. The method according to claim 1, wherein the step of providing a transparent optical element comprises:
providing a frame member; and
attaching the transparent optical element to the frame member.

13. The method according to claim 1, wherein providing a transparent optical element comprises mounting the transparent optical element to the photo mask, so as to serve as a backside pellicle for the photo mask.

14. The method according to claim 13, wherein the transparent optical element is mounted with the frame member to the photo mask, so as to achieve a gas tight sealing of the backside of the photo mask.

15. The method according to claim 14, wherein the gas tight sealing of the backside of the photo mask is achieved by gluing the frame member to the backside of the photo mask.

16. The method according to claim 1, wherein providing a transparent optical element comprises providing the transparent optical element as a quartz plate.

17. The method according to claim 1, wherein providing a transparent optical element further comprises providing the attenuating elements being optically opaque to the light transmitted from the light source and being formed in varying dimensions and densities so as to resemble the first intensity correction function.

18. The method according to claim 17, wherein the opaque elements comprise chrome.

19. The method according to claim 1, wherein providing a transparent optical element comprises providing the attenuating elements as phase grating elements being formed so as to resemble the first intensity correction function.

20. The method according to claim 1, wherein providing a transparent optical element comprises:
providing the attenuating elements as semi-transparent elements to the light transmitted from the light source; and
providing the attenuating elements in varying dimensions and densities so as to resemble the first intensity correction function.

21. The method according to claim 20, wherein the semi-transparent elements comprise molybdenum silicide.

22. The method according to claim 1, wherein providing a transparent optical element comprises providing the attenuating elements by creating shading elements within the quartz plate of the transparent optical element.

23. The method according to claim 22, wherein the shading elements within the quartz plate of the transparent optical element are formed by employing a pulsed laser.

24. A method for improving dimensional accuracy in a photolithographic system, the method comprising:
providing a layout pattern having a plurality of structural elements each having a characteristic feature size being described by a nominal value;
providing a photo mask having a mask pattern corresponding to the layout pattern;
providing a photolithographic apparatus having a light source and being capable to accommodate the photo mask;
projecting the mask pattern on a photo resist layer on a surface of a substrate using the photolithographic apparatus;
forming a resist pattern having a plurality of structural elements corresponding to the layout pattern, wherein each of the structural elements have at least one characteristic feature size;
determining variations of the at least one characteristic feature size of the structural elements of the resist pattern as compared to the nominal values of the structural elements of the layout pattern;
apportioning the variations of the at least one characteristic feature size into a first contribution being associated with the photolithographic apparatus and into a second contribution being associated with the photo mask;
calculating a first intensity correction function according to the first contribution of the variation of the at least one characteristic feature size;
calculating a second intensity correction function according to the second contribution of the variation of the at least one characteristic feature size;
providing a transparent optical element having a plurality of attenuating elements being arranged in accordance with the first intensity correction function and having a further plurality of attenuating elements being arranged in accordance with the second intensity correction function; and
introducing the transparent optical element in the photolithographic apparatus in a region between the photo mask and the light source, so as to improve the dimensional accuracy during projection of the mask pattern.

25. The method according to claim 24, wherein the attenuating elements being arranged in accordance with the first intensity correction and the attenuating elements being arranged in accordance with the second intensity correction are arranged on the front surface of the transparent optical element.

26. The method according to claim 24, wherein the attenuating elements being arranged in accordance with the first intensity correction are arranged on the front surface of the transparent optical element and the attenuating elements being arranged in accordance with the second intensity correction are arranged on the back surface of the transparent optical element.

27. The method according to claim 24, wherein the attenuating elements being arranged in accordance with the first intensity correction are arranged on the front surface or on the back surface of the transparent optical element and the attenuating elements being arranged in accordance with the second intensity correction are arranged as phase grating elements being formed on the back side of the photo mask.

28. The method according to claim 24, wherein the attenuating elements being arranged in accordance with the first intensity correction are arranged on the front surface of the transparent optical element and the attenuating elements being arranged in accordance with the second intensity correction are arranged by creating shading elements within the photo mask.

29. The method according to claim 28, wherein the shading elements within the photo mask of the transparent optical element are formed by employing a pulsed laser.

30. The method according to claim 24, further comprising:
providing one or more third intensity correction functions being associated with one or more further projection apparatus; and
providing the transparent optical element having one or more further regions having a further plurality of attenuating elements being arranged in accordance with the one or more third intensity correction functions.

31. The method according to claim 24, further comprising:
providing one or more third intensity correction functions being associated with one or more further exposure fields of the projection apparatus; and
providing the transparent optical element having one or more further regions having a further plurality of attenuating elements being arranged in accordance with the one or more third intensity correction functions.

32. The method according to claim 24, further comprising:
providing one or more third intensity correction functions being associated with one or more further mask patterns used in the projection apparatus; and
providing the transparent optical element having one or more further regions having a further plurality of attenuating elements being arranged in accordance with the one or more third intensity correction functions.

33. The method according to claim 24, further comprising selecting the respective region on the transparent optical element according to the mask pattern and/or exposure fields of the projection apparatus and/or projection apparatus and/or illumination conditions.

34. The method according to claim 24, further comprising:
providing the transparent optical element having one or more further regions on separate transparent plates;
providing a rotary plate;
mounting the separate transparent plates on the rotary plate;
inserting the rotary plate into the projection apparatus; and
selecting the respective separate transparent plate according to the mask pattern and/or exposure field of the projection apparatus.

35. The method according to claim 34, wherein the projection apparatus further comprises an illumination optics having at least two lenses and wherein the rotary plate is positioned such that the respective separate transparent plate used during lithographic projection can be placed within the illumination optics between the two lenses in a certain defocusing distance from a conjugated plane of the mask pattern of the photo mask.

36. The method according to claim 35, wherein the certain distance from the conjugated plane of the mask pattern of the photo mask is selected between about 1 mm and about 10 mm.

37. The method according to claim 24, wherein the projection apparatus further comprises an illumination optics having at least two lenses and wherein the transparent optical element having one or more further regions is positioned such that the respective separate transparent plate used during lithographic projection can be placed within the illumination optics between the two lenses in a certain defocusing distance from a conjugated plane of the mask pattern of the photo mask.

38. The method according to claim 37, wherein the certain distance from the intermediate plane of the illumination slit is selected between about 1 mm and about 10 mm.

39. A system for improving dimensional accuracy in a photolithographic system, the system comprising:
a photo mask having a mask pattern corresponding to a layout pattern, the layout pattern having a plurality of structural elements each having a characteristic feature size being described by a nominal value;
a photolithographic apparatus having a light source and being capable to accommodate the photo mask and to project the mask pattern on a photo resist layer on a surface of a substrate;
means for forming a resist pattern having a plurality of structural elements corresponding to the layout pattern, wherein each of the structural elements has a characteristic feature size;
means for determining variations of the characteristic feature size of the structural elements of the resist pattern as compared to the nominal values of the structural elements of the layout pattern;
means for apportioning the variations of the characteristic feature size into a first contribution being associated with the photolithographic apparatus and into a second contribution being associated with the photo mask;
means for calculating a first intensity correction function according to the first contribution of the variation of the characteristic feature size;
a transparent optical element having a plurality of attenuating elements being arranged in accordance with the first intensity correction function; and
means for introducing the transparent optical element in the photolithographic apparatus in a region between the photo mask and the light source, so as to improve the dimensional accuracy during projection of the mask pattern.

40. The system according to claim 39, wherein the transparent optical element is formed as a plate having a front surface and a back surface, wherein the front surface and the back surface are arranged substantially parallel to each other and wherein the front surface is facing to the photo mask.

41. The system according to claim 40, wherein the front surface of the transparent optical element is covered by an antireflective coating.

42. The system according to claim 41, wherein the back surface of the transparent optical element is covered by an antireflective coating.

43. The system according to claim 42, wherein the transparent optical element further includes structural elements forming a first alignment mark.

44. The system according to claim 43, wherein the first alignment mark is formed on the front surface of the transparent optical element.

45. The system according to claim 43, wherein the photo mask further comprises a second alignment mark on a surface of the photo mask.

46. The system according to claim 45, wherein the first alignment mark and the second alignment mark are formed as a box-in-box or box-in-frame or frame-in-frame structure.

47. The system according to claim 45, wherein the transparent optical element and the photo mask comprise further first alignment marks and further respective second alignment marks, so as to perform an alignment in at least two directions between the transparent optical element and the photo mask.

48. The system according to claim 39, wherein the transparent optical element comprises a frame member that is attached to the transparent optical element.

49. The system according to claim 39, wherein the transparent optical element is mounted to the photo mask, so as to serve as a backside pellicle for the photo mask.

50. The system according to claim 39, wherein the transparent optical element comprises a quartz plate.

51. The system according to claim 39, wherein the transparent optical element further comprises attenuating elements being optically opaque to the light transmitted from the light source and being formed in varying dimensions and densities so as to resemble the first intensity correction function.

52. The system according to claim 51, wherein the opaque attenuating elements comprise chrome.

53. The system according to claim 39, wherein the transparent optical element further comprises attenuating elements comprising phase grating elements being formed so as to resemble the first intensity correction function.

54. The system according to claim 39, wherein the transparent optical element comprises attenuating elements as semi-transparent elements to the light transmitted from the light source and being formed in varying dimensions so as to resemble the first intensity correction function.

55. The system according to claim 54, wherein the semi-transparent elements comprise molybdenum silicide.

56. The system according to claim 39, wherein the transparent optical element comprises attenuating elements by creating shading elements within the quartz plate of the transparent optical element.

57. The system according to claim 39, further comprising means for calculating a second intensity correction function according to the second contribution of the variation of the characteristic feature size, and wherein the transparent optical element has a further plurality of attenuating elements that are arranged in accordance with the second intensity correction function.

58. The system according to claim 57, wherein the plurality of attenuating elements and the further plurality of attenuating elements are arranged on the front surface of the transparent optical element.

59. The system according to claim 57, wherein the plurality of attenuating elements are arranged on the front surface of the transparent optical element and the further plurality of attenuating elements are arranged on the back surface of the transparent optical element.

60. The system according to claim 57, wherein the plurality of attenuating elements are arranged on the front surface of the transparent optical element and the further plurality of attenuating elements are arranged by creating shading elements within the photo mask.

61. The system according to claim 39, further comprising means for providing one or more further first intensity correction functions being associated with one or more further exposure fields of the projection apparatus and wherein the transparent optical element has one or more further regions with a further plurality of attenuating elements being arranged in accordance with one or more third intensity correction functions.

62. The system according to claim 39, further comprising means for providing one or more third intensity correction functions being associated with one or more further mask patterns used in the projection apparatus and wherein the transparent optical element has one or more further regions with a further plurality of attenuating elements being arranged in accordance with the one or more third intensity correction functions.

63. The system according to claim 61, wherein the transparent optical element has one or more further regions on separate transparent plates further comprising:
a rotary plate onto which the separate transparent plates are mounted;
means for inserting the rotary plate into the projection apparatus; and
means for selecting the respective separate transparent plate according to the mask pattern and/or exposure fields of the projection apparatus.

64. The system according to claim 63, wherein the projection apparatus further comprises an illumination optics having at least two lenses and wherein the rotary wheel is positioned such that the respective separate transparent plate used during lithographic projection is placed between the two lenses in a certain distance from a conjugated plane of the mask pattern of the photo mask.

65. The system according to claim 64, wherein the certain distance from the conjugated plane of the mask pattern of the photo mask is between about 1 mm and about 10 mm.

66. A method for improving dimensional accuracy in a photolithographic system, the comprising:
providing a layout pattern having a plurality of structural elements each having a characteristic feature size being described by a nominal value;
providing a photo mask having a mask pattern corresponding to the layout pattern;
providing a photolithographic apparatus having a light source and being capable to accommodate the photo mask;
projecting the mask pattern on a photo resist layer on a surface of a substrate using the photolithographic apparatus;
forming a resist pattern having a plurality of structural elements corresponding to the layout pattern, wherein each of the structural elements have at least one first characteristic feature size;
determining variations of the at least one first characteristic feature size of the structural elements of the resist pattern as compared to the nominal values of the structural elements of the layout pattern;
apportioning the variations of the at least one first characteristic feature size into a first contribution being associated with the photolithographic apparatus and into a second contribution being associated with the photo mask;
calculating a first intensity correction function according to the first contribution of the variation of the at least one characteristic feature size;
providing a first transparent optical element having a plurality of attenuating elements being arranged in accordance with the first intensity correction function;
introducing the transparent optical element in the photolithographic apparatus in a region between the photo mask and the light source, so as to improve the dimensional accuracy during projection of the mask pattern;
projecting the mask pattern on a photo resist layer on a surface of a second substrate using the photolithographic apparatus;
forming a second resist pattern having a plurality of structural elements corresponding to the layout pattern, wherein each of the structural elements have at least one second characteristic feature size;
determining variations of the at least one second characteristic feature size of the structural elements of the second resist pattern as compared to the nominal values of the structural elements of the layout pattern;
calculating a third intensity correction function according to the variation of the at least one second characteristic feature size; and
replacing the first transparent optical element by a second transparent optical element having a plurality of attenuating elements being arranged in accordance with a combination of the first intensity correction function and the third intensity correction function.

67. The method according to claim 66, wherein the second transparent optical element is obtained from the first transparent optical element by adding the plurality of attenuating elements according to the third intensity function to the first transparent optical element.

68. The method according to claim 67, wherein the plurality of attenuating elements according to the third intensity function are introduced into the same surface of the transparent optical element as the plurality of attenuating elements according to the first intensity function.

69. The method according to claim 67, wherein the plurality of attenuating elements according to the third intensity function are introduced into a surface of the transparent optical element different to the surface the plurality of attenuating elements according to the first intensity function are introduced.

70. The method according to claim 66, wherein providing the photo mask comprises introducing shading elements according to the second intensity function by irradiating pulsed laser radiation through the back surface into the photo mask and substantially opposite pattern lines.
